(19) United States
(12) Patent Application Publication
(10) Pub. No.: US 2002/0094683 A1
(43) Pub. Date: Jul. 18, 2002

(54) Method for manufacturing chip size package and its structure

(75) Inventors: Spencer Su, Kaohsiung (TW); James Lai, Kaohsiung (TW); Lin Chien-Tsun, Kaohsiung (TW); Captain Chen, Yungkang City (TW); Allen Chen, Kaohsiung (TW); C.S. Yang, Kaohsiung (TW); Chang Chao-Chia, Kaohsiung (TW); Kevin Hsia, Kaohsiung (TW)

Correspondence Address: DOUGHERTY & TROXELL, 5205 LEESBURG PIKE, SUITE 1404, FALLS CHURCH, VA, 22041, US

(73) Assignee: Walsin Advanced Electronics LTD

(21) Appl. No.: 09/760,764

(22) Filed: Jan. 17, 2001

(51) Int. Cl. H01L 21/302; H01L 21/461

(52) U.S. Cl. 438/689

(57) ABSTRACT

A method for manufacturing a chip size package comprises the steps of: providing a chip having a plurality of bonding pads on its active surface; providing a metal board consisting of the upper layer and the lower layer, wherein, a chip carrier, corresponding to said least chip, being formed on the surface of the upper layer of the said metal board; selectively etching the upper layer of the metal board to form a plurality of redistribution conductive circuits supported by the lower layer of the metal board; securing the chip to the chip carrier of the upper layer of the metal board, and electrically connecting to the conductive circuits; providing a package body (or underfill) in between the chip and the upper layer of the metal board; and, removing the lower layer of the metal board. Thus, package manufactured by applying present invention has ability of securing more electrodes and thinner thickness.

### BACKGROUND OF THE INVENTION

1. Field of the Invention

The present invention relates to a method for manufacturing a chip size package (CSP) and, in particular, to a method for manufacturing a chip size package using no chip pad and having redistribution conductive circuits.

2. Description of the Prior Art

Packages in the same size of, or slightly larger than the chips they pack are always called chip size package, CSP. Comparing to both bare chip and flip chip, chip size package has better protection to resist dust and humidity.

Generally, there is an interposer added into chip size package between chip and solder balls. The interposer could be substrate or lead frame. Wherein, to use substrate has a drawback of thicker package thickness and higher cost, and to use lead frame has a drawback of bad effect of redistribution and cannot pack chip having multi-electrodes. As described in US Pat. No. 5894107, a chip size package structure uses two lead frames, wherein, the first lead frame provides lead finger for chip to be secured to, and the second lead frame provides bumps for out electrical connection. By using dam tar to stabilize lead fingers of the first lead frame, the lead fingers have no enough stability and are easy to shift, and for shape of the lead fingers being limited, the package has no best redistribution effect.

Or, as described in U.S. Pat. No. 5951804, a method for chip size package first uses a TAB (Tape Automated Bonding) to stick to the reverse side of a lead frame, then encapsulates together with chip and TAB tape after securing chip and TAB tape, and results in a CSP package structure. The method has to stick a polyimide tape and encapsulate a plurality of place. Not only the TAB tape is difficult to process and the cost is high, but also increases thickness of the CSP package structure.

### SUMMARY OF THE INVENTION

Therefore, one object of present invention is to provide a method for manufacturing the chip size package which selectively etch the upper layer of a metal board to form the redistribution conductive circuits, thus a chip having general distributed bonding pads can be used in a chip size package.

The other object of present invention is to provide a method for manufacturing the chip size package, which selectively etch the upper layer of a metal board to form the redistribution conductive circuits, thus chip size packages having multi-electrodes can be produced.

Again, the other object of present invention is to provide a chip size package, wherein, the redistribution conductive circuits of the chip size package being stabilized by the lower layer of a metal board, as well as by the underfill-liked package body after encapsulation respectively during the manufacturing process. Thus, the package uses no chip pad, has thinnest thickness, provides best dispersedness of distribution of out electrical connection points and increase yield of securing surface of chip size package to circuit board.

According to the method for manufacturing a chip size package, the steps of the method comprises:

providing at least a chip having a plurality of bonding pads on its active surface;

providing a metal board consisting of the upper layer and the lower layer, wherein, a chip carrier, corresponding to said chip, being formed on the surface of the upper layer of said metal board;

selectively etching the upper layer of the metal board so as to form a plurality of redistribution conductive circuits;

securing the chip to the chip carrier of the upper layer of the metal board, and electrically connecting to the conductive circuits;

encapsulating topside of the chip and the upper layer of the metal board; and removing the lower layer of the metal board.

### BRIEF DESCRIPTION OF THE DRAWINGS

FIG. 1 is a perspective view showing the bonding pads located on perimeter of active surface of the chip;

FIG. 2 is a perspective view, corresponding to FIG. 1, showing redistribution conductive circuits that are formed from selectively etching a metal board according to the manufacturing process of present invention;

FIG. 3a is a cross-sectional view, along line 3-3, showing securing the chip in FIG. 1 to the selectively etched metal board in FIG. 2 according to the first embodiment of present invention;

FIG. 3b is a cross-sectional view showing the secured structure after removing the lower layer of metal board as shown in FIG. 3a according to the first embodiment of present invention;

FIG. 4a is a cross-sectional view, along line 3-3, showing securing the chip in FIG. 1 to the metal board after selectively etching and partly electroplate in FIG. 2 according to the second embodiment of present invention;

FIG. 4b is a cross-sectional view showing the secured structure after partly removing the lower layer of metal board in FIG. 4a according to the second embodiment of present invention;

FIG. 5 is a perspective view showing bonding pads located on the middle portion of active surface of the chip;

FIG. 6 is a perspective view showing redistribution conductive circuits formed from partly etching a metal board corresponding to FIG. 5 according to process method of present invention;

FIG. 7a is a cross-sectional view, along line 7-7, showing securing the chip in FIG. 5 to the selectively etched metal board in FIG. 6 according to the third embodiment of present invention;

FIG. 7b is a cross-sectional view showing the secured structure after removing the lower layer of metal board in FIG. 7a according to the third embodiment of present invention;

FIG. 8a is a cross-sectional view, along line 7-7, showing securing the chip in FIG. 5 to the metal board after selectively etching and partly electroplating in FIG. 6 according to the fourth embodiment of present invention; and

FIG. 8b is a cross-sectional view showing the secured structure after partly removing the lower layer of metal board in FIG. 8a according to the fourth embodiment of present invention.

### DETAILED DESCRIPTION OF THE PREFERRED EMBODIMENT

Referring now to the drawings, the chip size packages according to the individual embodiments of the present invention will be described.

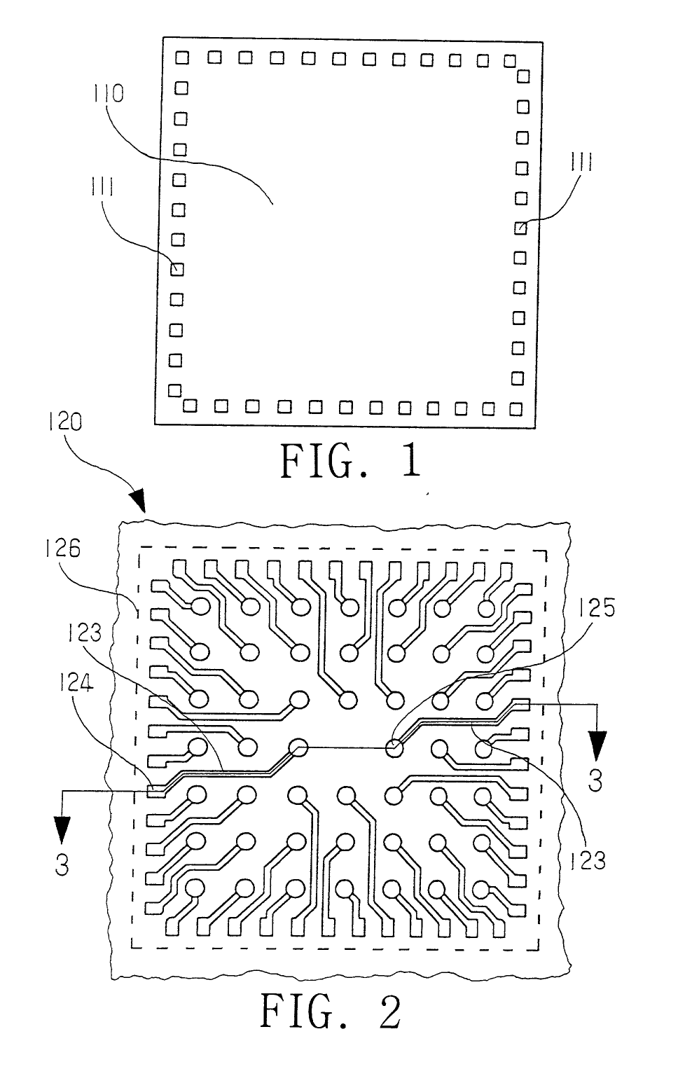

FIG. 1, 2, 3a, and 3b are views showing the result of each step in the method for manufacturing process of a chip size package according to the first embodiment of the present invention.

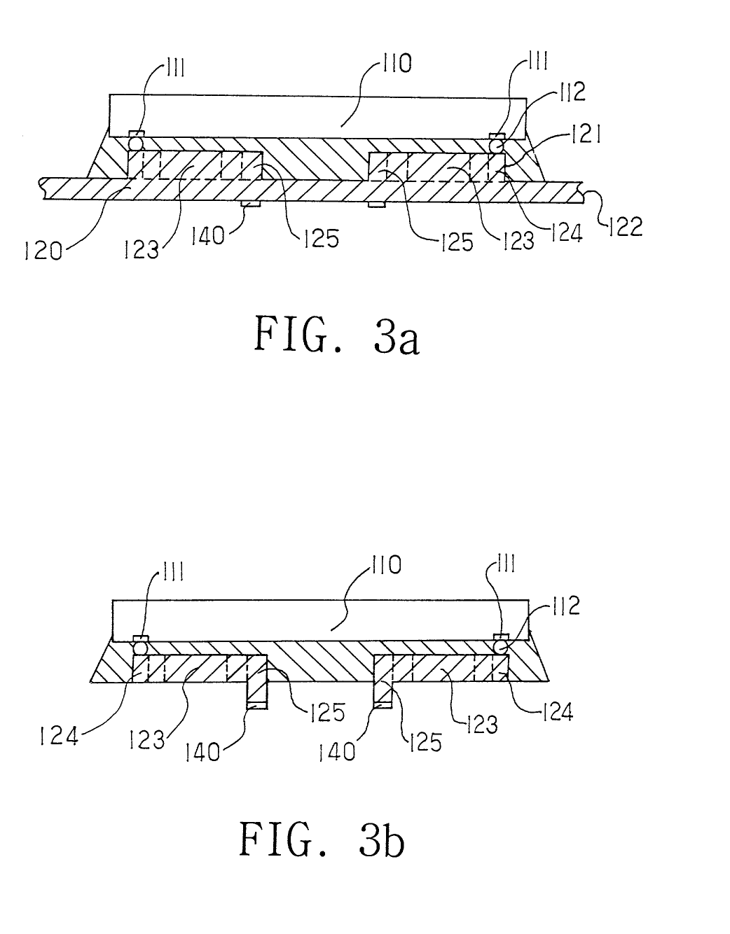

As shown in FIG. 1, in step of providing at least a chip 110, wherein, the chip 110 has a plurality of bonding pads 111 on its active surface and it is in habitually used chip form. The bonding pads 111, near perimeter of active surface of the chip 110, arranged closely to each other, are secured to the near lead fingers or substrate during wire bonding in well-known encapsulation process. Though, there are conductive bumps 112 formed on the bonding pads 111 and the chip becomes flip chip mounted as shown in FIG. 3a, for wire bonding or bump securing in a encapsulation structure, generally speaking, pitch between bonding pads 111 of the chip 110 is very tiny (about 40 to 100 μm). Since the securing distance is too short, it is not suitable for the flip chip securing to the circuit board directly

FIG. 2. shows step of providing a metal board 120, wherein, the metal board consists of the upper layer 121 and the lower layer 122 (referring to FIG. 3a). A chip carrier is formed on surface of the metal board 120 corresponding to the said least chip 110. The metal board could be a copper tinsel layer provided as lead frame of chip size package for the chip 110.

Then, shown in FIG. 2 and 3a is step of partly etching the upper layer 121 of the metal board 120 to form a plurality of redistribution conductive circuits 123. The lower layer 122 of the metal board 120 supports the plurality of redistribution conductive circuits 123. That is, the plurality of redistribution conductive circuits 123 protrudes from and also supported by the lower layer 122 of the metal board 120. Etch the upper layer 121 of the metal board 120 and leave only conductive circuits 123. The conductive circuits are of different length and in any demanded curve shape. Using well-known technology, such as using mask to cover path for the conductive circuits of the upper layer 121 of the metal board 120, and then process selectively etching, can form the conductive circuits 123. The plurality of conductive circuits 123 all has respective connected first end 124 and second end 125. The first end 124 is corresponding to the bonding pad 111 of the chip 110 and near perimeter of the chip carrier 126 for inner electrical connection for the bonding pad 111 of the chip 110. The second end 125 distributes over the chip carrier 126 to provide out electrical connection of chip size package. For adjacent second ends 125 distributing more dispersedly and evenly than adjacent first ends 124 doing, out electrical connection of the chip 110 leans on the second ends 125 of the conductive circuits 123 to redistribute its layout. Besides, the conductive circuits 123 can also seen as lead fingers of lead frame of chip size package.

FIG. 3a shows securing said chip 110 to the upper layer 121 of the metal board 120 and using bumps 112 to electrically connect between the bonding pads 111 of the chip 110 and the first ends 124 of the conductive circuits 123. As shown in FIG. 3a, for the bonding pads 111 of the chip 110 being located near perimeter of active surface, since the conductive circuits 123 should match up corresponding bonding pads 111, the first ends 124 extend to the second ends 125 from outside to inside with different length and the second pads 125 distribute evenly over the chip carrier 126. For using bumps 112 as electrical connection between bonding pads 111 of chip 110 and the first ends 124 of the conductive circuits 123, the chip 110 in flip flop type is secured to the chip carrier 126 of the upper layer 121 of the metal board 120 by methods of re-flow or other. Since, the plurality of conductive circuits 123 is shaped up in one with and supported by the lower layer 122 of the metal board 120, there will be no shifting or even resulting in falling off condition during securing. Package manufactured by using this method is far more stable than by well-known lead frame which uses surrounding dam bar to connect fixed lead finger. The conductive circuits 123 can also be shaped to any demanded length and curve path. To reduce stress due to different coefficient expansion between chip 110 and the conductive circuits 123, an underfill 130 made from thermosetting liquid epoxy compound or other material is provided in between active surface of the chip 110 and the upper layer 121 of the metal board 120. The underfill 123 is formed by re-flow process at the same time with securing bonding pads 111 of chip 110 and the first ends 124 of the conductive circuits 123 and used as encapsulation for active surface of the chip 110 and surface of the upper layer 121 of the metal board 120.

FIG. 3b shows removing the lower layer 122 of the metal board 120 by etching and grinding or other methods. Thus, manufacture at least a chip size package structure and the chip size package structure comprises: a chip 110, having a plurality of bonding pads 111 on its lower surface (i.e. active surface), and bumps 112 being formed on said plurality of bonding pads 111; a plurality of redistribution conductive circuits 123 being formed from a metal board 120, each having connected first end 124 and second end 125, wherein the first end 124 being secured by the bump 111 to the bonding pad 111 of said the chip 110, and wherein the second end 125 being distributed over the corresponding lower surface of the chip 110; and an underfill 130 encapsulating space between the surface of the chip 110 and the plurality of conductive circuits 123, the underfill 130 becoming package body of the package structure. Plant solder ball or spread conductive paste on the second ends 125 for the package to securing to the circuit board (not shown in figure). Thus, manufacturing a chip size package and the process of producing chip size package according to the present invention has the following benefits: for using no substrate then having the thinnest thickness; for using the plurality of redistribution conductive circuits 123, then providing better disperse distribution of out electrical connection and better yield of securing the chip size package to circuit board.

Obviously, the method for manufacturing chip size package according to the present invention has the following ability. 1) The plurality of conductive circuits 123 is shaped up in one with and supported by the lower layer 122 of the metal board 120, there will be no shifting or even resulting in falling off condition during securing. 2) During the manufacturing process, since the conductive circuit 123 is fixed by the lower layer 122 of metal board 120 and adhered by the underfill 130 and bumps 112 after removing the lower layer 122 of metal board 120, thus the package uses no substrate and has thinner thickness. 3) For using dispersed second ends 123 of conductive circuits 123 as redistribution of out electrical connection of the chip 110 to increase distance of adjacent out connection points in a determined area, the package has ability of increasing correctness of securing.

Next, a second embodiment of manufacturing a chip size package of the present invention will be described. The steps of manufacturing process are quit the same as in the first embodiment, such as steps of providing a chip 110, providing a metal board 120, selectively etching the upper layer 121 of the metal board 120, securing the chip 110 to the upper layer 121 of metal board 120, providing a underfill 130, etc.

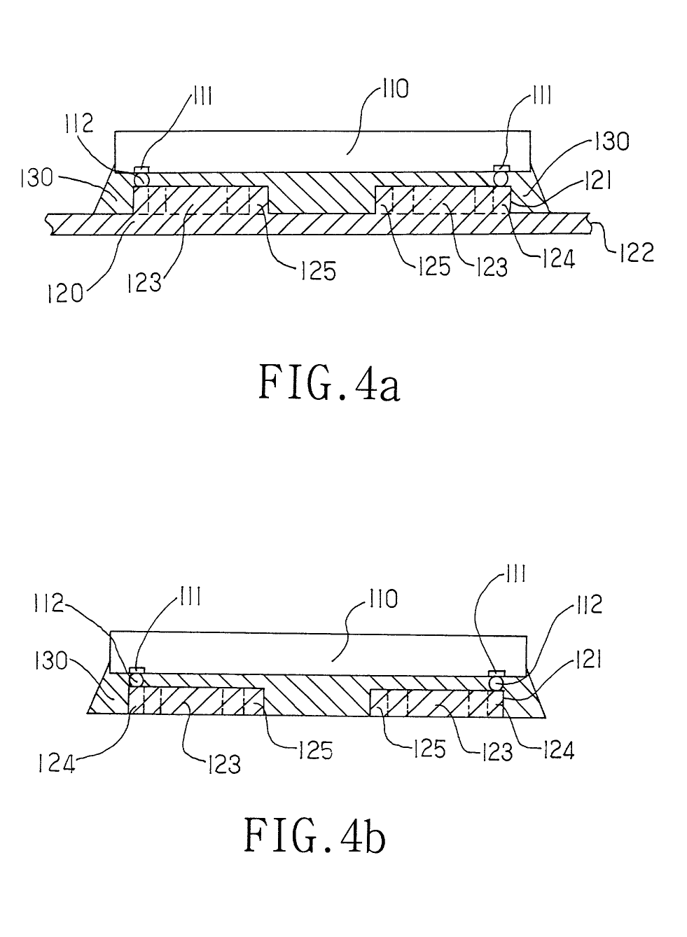

After securing the chip 110 to the upper layer 121 of the metal board 120 and providing a underfill 130, and before etching to remove lower layer 122 of the metal board 120, FIG. 4a shows the combination structure that the lower layer 122 of the metal board 120 is coated with a plurality of etching resistors 140 corresponding to the second ends 125 of the upper layer 121. The best practice of coating is to electroplate nickel or eutectic alloy of nickel (Ni/Pd/Au). Finally, in step of removing lower layer 122 of metal board 120, for coating the lower layer 122 corresponding to the second ends 125 of upper layer 121 with a plurality of etching resistors 140, the etching resistors 140 of the lower layer 122 will not be etched. FIG. 4b shows a chip size package after etching lower layer 122 of metal board 120, wherein the second ends 125 (thickness of upper layer 121 and lower layer 122) are thicker than the first ends 124 (thickness of only upper layer 121) and protrude outside the underfill 130, so that the chip size package can be secured to circuit board directly.

Of course, said step of partly coating the lower layer 122 of the metal board 120 with a plurality of etching resistors 140, or step of electroplating eutectic alloy might not a necessarily step of the manufacturing process in the present invention. Other way to provide the etching resistors 140 (electroplated layer) corresponding to the second ends 125 of the upper layer 123 is, in step of providing a metal board 120, to pre-form a plurality of etching resistors 140 (electroplating layer) on part lower layer 122 of the metal board 120 and then simplify the process and increase the manufacturing efficiency.

Besides, the method for manufacturing chip size package according to present invention does not limit to chip having bonding pad 111 near its perimeter. The third and the fourth embodiments according to the present invention proclaim methods for manufacturing chip size package with chips 210 having another type of distribution of bonding pads.

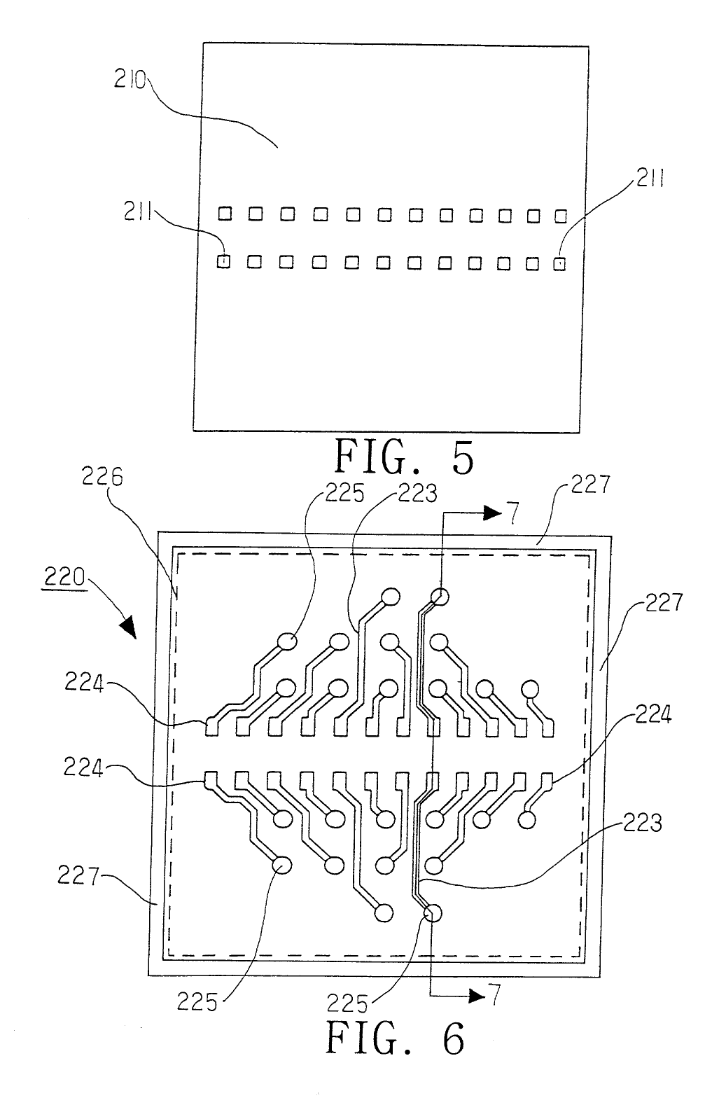

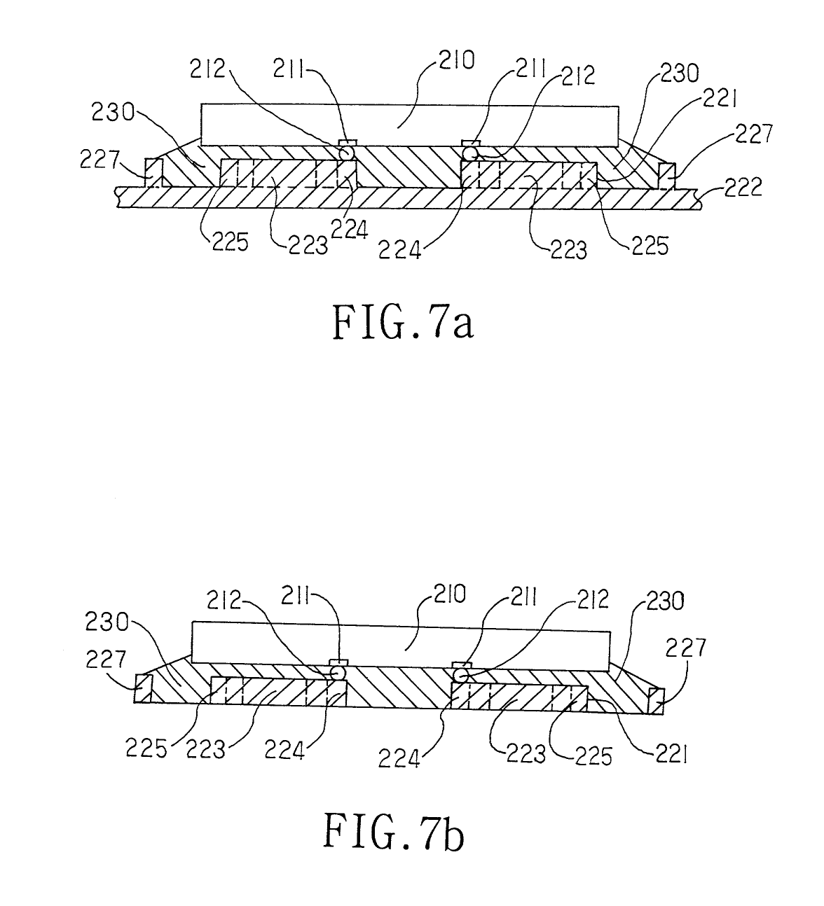

In the third embodiment according to present invention, the steps of manufacturing process are the same as in the first embodiment, except providing different type of chip. The steps comprises: providing a chip 210 (shown in FIG. 5), having a plurality of bonding pads 211 on its center of active surface; providing a metal board 220 (shown in FIG. 6); selectively etching the upper layer 221 of the metal board 220, except forming a plurality of redistribution conductive circuit 223, also forming a surrounding portion 227 near the chip carrier 226 to restrict the underfill 230, wherein, the conductive circuits 223 extending from the first ends 224 to the second ends inside out; securing the chip 210 to the chip carrier 226 of the upper layer 221 of the metal board 220; providing a underfill 230 in between the chip 210 and the upper layer 221 of the metal board 220 (shown in FIG. 7a); and, using grinding or etching to remove the lower layer 222 of the metal board 220 (shown in FIG. 7b):

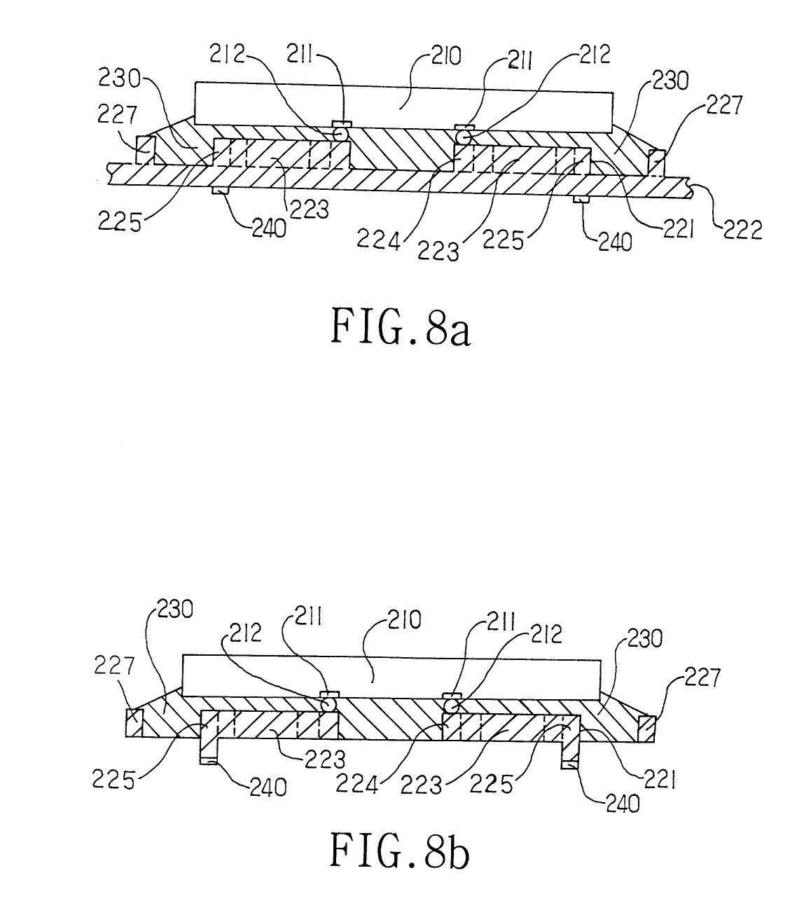

In the fourth embodiment according to present invention, the steps of manufacturing process are the same as the second embodiment, except providing different type of chip 210. Before etching to remove the lower layer 222 of the metal board 220, coat the lower layer 222 of the metal board 220 with a plurality of etching resistors 240 corresponding to the second ends 225 of the upper layer 221. For instance, electroplate nickel or eutectic metal of nickel (Ni/Pd/Au) and come out with a combination structure as shown in FIG. 8a. Finally, in step of removing lower layer 222 of metal board 220, FIG. 8b shows a chip size package after etching lower layer 222 of metal board 220, wherein the seconds 225 are thicker than the first ends 224 and protrude outside the underfill 230, so that the chip size package can be secured to circuit board directly.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a chip size package at least comprising the steps of:
providing at least a chip having a plurality of bonding pads;
providing a metal board consisting of upper layer and lower layer and the upper surface of metal board formed at least a chip carrier corresponding to said chip;
selectively etching upper layer of the metal board to form a plurality of conductive circuits for redistribution, and the lower layer of the metal board where the plurality of conductive circuits supported by, having connected first ends and second ends, wherein the first ends correspond to the bonding pads of the chip, and the second ends distributing over the chip carrier;
securing said chip to chip carrier of upper layer of metal board, and electrically connecting bonding pads of the chip and the first ends of conductive circuits;
encapsulating active surface of said chip and surface of said top layer of the metal board; and
removing said lower layer of the metal board.

2. The method for manufacturing a chip size package in accordance with claim 1, wherein in the removing step, grinding or etching is the means of removing the lower layer of metal board.

3. The method for manufacturing a chip size package in accordance with claim 1, before removing step further comprising:
coating a plurality of etching resistors on the lower layer of the metal board, and the etching resistors correspond to the second ends of the conductive circuits of the upper layer.

4. The method for manufacturing a chip size package in accordance with claim 3, wherein the etching resistors are made from electroplating nickel or nickel alloy.

5. The method for manufacturing a chip size package in accordance with claim 1, wherein in the step of providing a metal board:
a plurality of etching resistors are formed on the surface of the lower layer of the metal board and the etching resistors correspond to the second ends of the conductive circuits of the upper layer.

6. The method for manufacturing a chip size package in accordance with claim 1, wherein in the step of providing at least a chip, there are bumps formed on the corresponding bonding pads of said chip.

7. The method for manufacturing a chip size package in accordance with claim 1, wherein, in encapsulating step, an underfill is formed in between active surface of the chip and surface of the upper layer of the metal board; also, the securing step and the encapsulating step is processed simultaneously.

8. The method for manufacturing a chip size package in accordance with claim 1, wherein in the step of etching the upper layer of the metal board, a surrounding portion is formed around the chip carrier.

9. A chip size package comprising:
a chip having a plurality of bonding pads on its active surface, and bumps being formed on said plurality of bonding pads;
a plurality of redistribution conductive circuits being formed from a metal board, each having connected first end and second end, wherein the first end being secured by the bump to the bonding pad of said the least chip, and the second end being distributed over the corresponding the active surface of the chip; and
a package compound encapsulating space between the active surface of the chip and the plurality of conductive circuits.

10. A chip size package in accordance with claim 9, wherein the second ends of some conductive circuits are thicker than the first ends.

11. A chip size package in accordance with claim 9, wherein the bonding pads are closed to the perimeter of the active surface of the chip.

12. A chip size package in accordance with claim 9, wherein the bonding pads are closed to the middle portion of the active surface of the chip.

13. A method for manufacturing a chip size package at least comprising the steps of:
providing at least a chip having a plurality of bonding pads on its active surface;
selectively etching the upper layer of a lead frame to form a plurality of lead fingers, which supported by the lower layer of lead frame and consisting of connected first ends and second ends, wherein, the first ends are corresponding to the bonding pads of the chip, and the second ends are used as out electrical connection point of said chip;
securing the said chip to the upper layer of the lead frame in a flip chip configuration, and the bonding pads of the chip being electrically connected to the first ends of the plurality of lead fingers of lead frame;
providing an underfill between the chip and the upper layer of lead frame; and
removing the lower layer of lead frame.

14. The method for manufacturing a chip size package in accordance with claim 13, wherein, in the removing step, etching is the means of removing the lower layer of lead frame.

15. The method for manufacturing a chip size package in accordance with claim 14, before removing step further comprising:
coating a plurality of etching resistors on the lower layer of the lead frame, and the etching resistors correspond to the second ends of the lead fingers of the upper layer of lead frame.

16. The method for manufacturing a chip size package in accordance with claim 13, wherein, in the step of selectively etching upper layer of a lead frame, a plurality of etching resistors are formed on the surface of the lower layer of lead frame, and the plurality of etching resistors correspond to the second ends of lead fingers of upper layer.
